(19) United States
(12) Patent Application Publication
(10) Pub. No.: US 2025/0240909 A1
(43) Pub. Date: Jul. 24, 2025

(54) DOUBLE-AIR-DUCT LASER RADAR HEAT DISSIPATION STRUCTURE

(71) Applicant: GUILIN UNIVERSITY OF TECHNOLOGY, GUILIN (CN)

(72) Inventors: Guoqing ZHOU, GUILIN (CN); Angte CAI, GUILIN (CN)

(73) Assignee: GUILIN UNIVERSITY OF TECHNOLOGY, GUILIN (CN)

(21) Appl. No.: 19/002,764

(22) Filed: Dec. 27, 2024

(30) Foreign Application Priority Data
Jan. 23, 2024 (CN) 202410090894.1

(51) Int. Cl. H05K 7/20; G01S 7/481

(52) U.S. Cl. CPC H05K 7/20145; G01S 7/481; H05K 7/20154; H05K 7/20209

(57) ABSTRACT

A double-air-duct laser radar heat dissipation structure includes a radar box body, a first and a second heat dissipation portion. The first heat dissipation portion for heat dissipation of a high-speed acquisition module comprises two air duct structures and an air duct switching mechanism. When an unmanned aerial vehicle works, a first air duct improves heat dissipation of a radar system through an air flow generated by the unmanned aerial vehicle; after landing, the air duct switching mechanism disconnects the first air duct and connects a second air duct to a heat dissipation system to meet heat dissipation of a laser radar in a data processing stage. The second heat dissipation portion completes heat dissipation of a laser device through TEC refrigeration and a heat sink. The present disclosure reduces energy consumption and makes the radar adapt to various working conditions while improving the heat dissipation.

### CROSS-REFERENCE TO RELATED APPLICATION

This application claims the priority benefit of China application serial no. 202410090894.1, filed on Jan. 23, 2024. The entirety of the above-mentioned patent application is hereby incorporated by reference herein and made a part of this specification.

### BACKGROUND

### Technical Field

The present invention relates to the technical field of laser radars, and particularly to an unmanned aerial vehicle-mounted laser radar heat dissipation mechanism.

### Description of Related Art

With the rapid development of science and technology, a method of measuring a water depth by a laser radar has gradually entered people's vision, and compared with a traditional method of measuring a water depth by multiple beams, the method of measuring the water depth by the laser radar has the advantages of high speed, high precision and good flexibility. Meanwhile, with the development of unmanned aerial vehicle technology, the two technologies may be organically combined, so that the laser radar is not easily limited by time and space, thus greatly increasing an operating scope.

Considering large absorption and attenuation coefficients of water, in order to realize underwater target detection, the laser radar needs high emission energy, high repetition frequency and fast imaging speed, which inevitably leads to a large amount of heat generated by the laser radar in a working process, so that it is necessary to arrange a heat dissipation device to effectively export heat generated by a system. In addition, when the system is operated high above the ground, the laser radar system can dissipate heat through an air flow generated by the unmanned aerial vehicle. However, when the laser radar completes detection high above the ground and carries out the subsequent work after landing, a radiating fin cannot be effectively supplied with air, which greatly reduces the heat dissipation efficiency of the laser radar system.

At present, the laser radar mainly uses an air cooling or liquid cooling technology to dissipate heat, and the liquid cooling heat dissipation is to take the heat out of the system with a cooling liquid. In the invention patent with application number CN202211487369.0 titled a high-precision single-wavelength mie-scattering laser radar from Chen Hao of Zhenjiang Kena Intelligent Technology Co., Ltd., a heat conduction liquid and a small water pump are used to quickly transfer the heat generated by the laser radar to a heat conduction frame, and meanwhile, a hydraulic lifting heat dissipation block is used to adjust a contact area between a heat dissipation structure and the air, thus improving the heat dissipation efficiency. In the invention patent with application number CN202111156637.6 titled a laser radar heat dissipation mechanism from Zhao Xiaona, et al. of Wuhan University, a heat dissipation mechanism is provided, which enables the laser radar to effectively dissipate heat when a vehicle is parked, and the heat dissipation structure comprises a fan and a large number of liquid cooling devices, so that the overall structure is complex and has a risk of liquid leakage, and meanwhile, this structure is only suitable for mounting on the vehicle.

The air cooling heat dissipation is mainly to generate a forced air flow generated by the outside or heat dissipation structures such as a heat dissipation fan to take the heat out of the laser radar. In the invention patent with application number CN202210516570.0 titled a heat dissipation structure for a laser radar and a laser radar with the heat dissipation structure from Jin Lingjie of Yantai IRAY Technology Co., Ltd., a bottom air flow channel and a vertical air flow channel form a chimney structure, and a chimney effect is used to enhance an air flow speed, so as to finally improve an overall heat dissipation effect. However, due to a large height of the whole structure, this structure is not suitable for some occasions with height requirements. In the invention patent with application number CN202223551342.1 titled a laser radar heat dissipation assembly from Cao Kaifa, et al. of Anhui Technovo Lidar Technology Co., Ltd., which is a heat dissipation net is used to improve a heat dissipation effect of an air cooling system. In the invention patent with application number CN202222256908.1 titled a laser radar heat dissipation system from Chen Chao, et al. of Wuhan VanJee Technology Co., Ltd., heat exchange between an inner tube and an outer tube is adopted, and hot gas in the inner tube is driven by an air pump to flow rapidly, so as to accelerate heat exchange with cold gas in the outer tube, thus improving a heat dissipation effect. In the invention patent with publication number WO2022155071A1 titled a Fanless Design of a Rotating LiDAR System with Integrated Cleaning and Cooling from Karayacoubian Paul, et al. of ARGO AI Co., Ltd., a plurality of fins are added to a shell of a rotary laser radar, so as to enhance a heat exchange capacity of the shell. In the invention patent with publication number WO2019052922A1 titled a LiDAR Arrangement Comprising Flow Cooling from Hattass Mirko, et al. of BOSCH Company, an internal rotating structure of the laser radar is used as a driving member to form an internal circulating heat dissipation system, thus improving the heat dissipation efficiency. In the invention patent with publication number US2022317256A1 titled a Lidar from Zhang Chao, et al. of Hesai Technology Co., Ltd., heat is transferred to a shell wall through a plurality of heat dissipation structures, so as to solve the reliability problem of the laser radar caused by overheating.

It can be concluded from the above reviews that, although these liquid cooling heat dissipation inventions can meet heat dissipation requirements of the laser radar, their characteristics of heavy weight, large volume and high energy consumption can increase a burden of an unmanned aerial vehicle-mounted device and reduce an endurance of the unmanned aerial vehicle, and meanwhile, the liquid cooling device has a risk of liquid leakage, which reduces the stability of the radar system. The air cooling heat dissipation inventions have the characteristics of small volume and simple structure, but most of them focus on a single working situation, without aiming at an external environment change of the radar, which may easily lead to insufficient heat dissipation of the laser radar under certain circumstances.

### SUMMARY

In order to solve the above problems, the present invention is specifically implemented by the following technical solution.

The present invention comprises a radar box body, a box cover, a laser device heat dissipation structure and a data acquisition module heat dissipation structure, wherein left and right sides of the radar box body are provided with an air introduction pipeline, which introduces an air flow generated by an unmanned aerial vehicle into the radar box body; a front side of the radar box body is provided with an air outlet and a first heat dissipation fan; and left and right sides of the box cover are provided with a first air inlet corresponding to the air introduction pipeline, and a groove is arranged in a central area to increase a contact area with air for assisting heat dissipation.

The data acquisition module heat dissipation structure is arranged on the right side of the radar box body, and comprises a first heat dissipation portion consisting of a first heat dissipation portion cover plate, a first heat dissipation portion shell cover, a wind board, a wind board rotating shaft, a counterweight, and a second air inlet arranged at a front end of the first heat dissipation portion shell cover and a second heat dissipation fan arranged in the second air inlet, a side surface on the right side of the radar box body is provided with a through hole communicated with the first heat dissipation portion shell cover, an air duct for introducing the air flow from the first air inlet on the right side of the box cover to the air introduction pipeline on the right side of the radar box body is the first air duct, and an air duct for introducing the air flow from the second air inlet to the air introduction pipeline on the right side of the radar box body is the second air duct; the wind board serves as a structure for switching between the first air duct and the second air duct, an auxiliary board is also arranged on the wind board rotating shaft for locking the wind board together with the counterweight when the second heat dissipation fan is turned on, and the air duct connected to the radar box body is determined by a position of the wind board; and the counterweight is arranged on two sides of the rotating shaft, and set at 10° away from a balance position of the counterweight in an initial state, which prevents the wind board from being opened due to unintended activation by a weak external air flow when the second heat dissipation fan is not turned on, and is also able to serve as main power in the latter half to open the wind board when the second heat dissipation fan is turned on.

The laser device heat dissipation structure comprises a second heat dissipation portion consisting of an air guide duct, a laser device heat sink, the first heat dissipation fan, a TEC refrigeration system integrated in the laser device and a control module, an air inlet of the laser device heat sink is communicated with the air introduction pipeline on the left side of the radar box body, an air outlet of the laser device heat sink is opposite to the air outlet of the radar box body, an air duct for introducing the air flow from the air inlet on the left side of the box cover to the laser device heat sink is the air guide duct, the air guide duct has an L-shaped structure, a plurality of columnar structures are arranged in the laser device heat sink to increase a contact area between the heat sink and the air, the laser device is arranged in the radar box body, the laser device heat sink is connected to a bottom surface of the laser device, the laser device transfers heat to the laser device heat sink through the TEC refrigeration system, the first heat dissipation fan is arranged in the air outlet, and the control module controls turning on and off and a rotating speed of the first heat dissipation fan.

An air duct switching flow of the data acquisition module heat dissipation structure is as follows: when wings of the unmanned aerial vehicle do not rotate, the second heat dissipation fan is turned on, the air flow is generated in the second air duct, and the air flow acts on the wind board to generate a torque effect on the wind board rotating shaft, so that the wind board starts to be opened, when the counterweight rotates across the balance position, the air flow in the second air duct completes a subsequent switching step together with the counterweight, when the counterweight reaches a limit position on a right side of the balance position, the wind board is completely opened, and at this time, the counterweight and the auxiliary board also prevent an air flow in a vertical direction from closing the wind board, so as to affect an air volume in heat dissipation; and after the wings of the unmanned aerial vehicle rotate and the second heat dissipation fan stops working, a downward air flow generated by the unmanned aerial vehicle closes the wind board again, and the first air duct is connected to the heat dissipation system again, so as to introduce the air flow generated by the unmanned aerial vehicle into the data acquisition module heat dissipation structure to enhance a heat dissipation effect.

According to the present invention, the air flow generated by the unmanned aerial vehicle is used to improve a heat dissipation capacity of the system, and different working conditions such as aerial operation and ground data processing are taken into account, so that power consumption is reduced while maintaining the stability of the system, and requirements of an unmanned aerial vehicle-mounted platform are met.

### BRIEF DESCRIPTION OF THE DRAWINGS

FIG. 1 is a schematic diagram of a structure of the present invention from an external perspective;

FIG. 2 is an exploded view of the structure of the present invention in an exploded state;

FIG. 3 is a schematic structural diagram of a wind board of the present invention in a closed state, that is, when a first air duct is connected to a heat dissipation system;

FIG. 4 is a schematic structural diagram of a counterweight of the present invention in a balanced state;

FIG. 5 is a schematic structural diagram of the wind board of the present invention in a completely open state, that is, when a second air duct is connected to the heat dissipation system;

FIG. 6 is a schematic structural diagram of a laser device heat sink of the present invention; and

FIG. 7 is a bottom cross-section view of the laser device heat sink of the present invention.

### DESCRIPTION OF THE EMBODIMENTS

Specific implementation of the present invention is further described in detail hereinafter with reference to the drawings, so as to clarify the objectives and advantages of the present invention.

### Embodiment

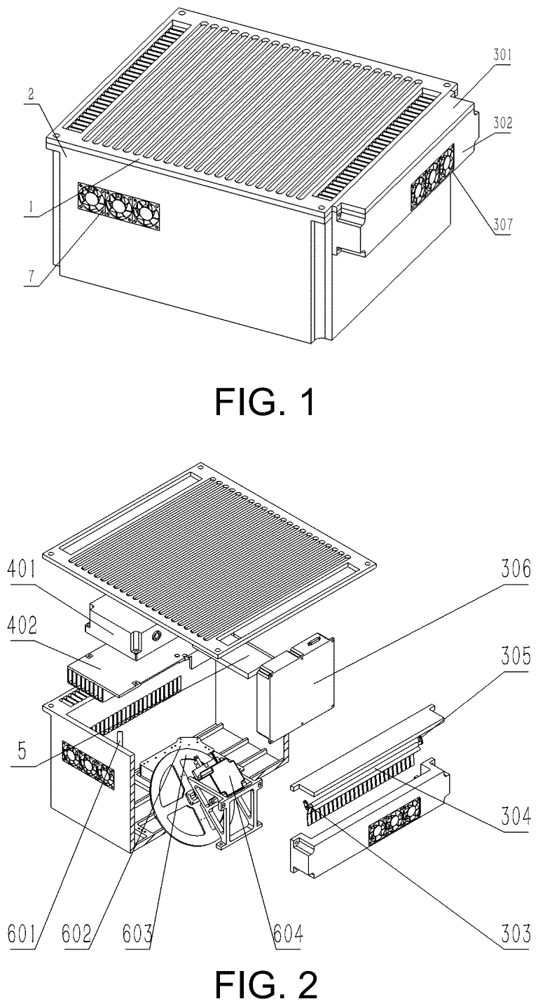

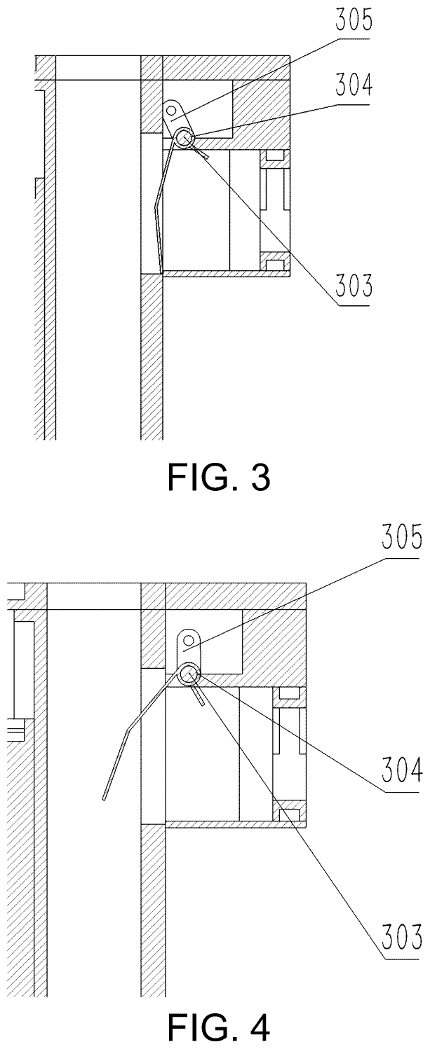

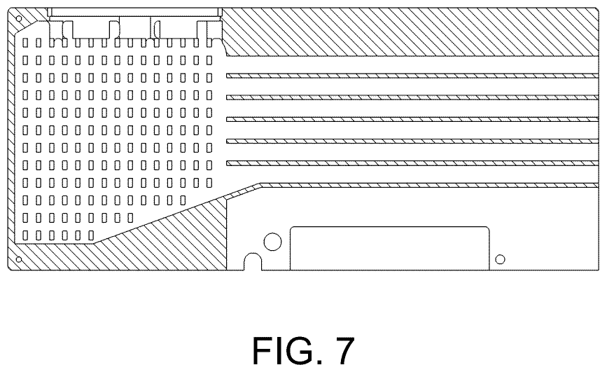

As shown in FIG. 1 to FIG. 7:

The present invention provides a laser radar heat dissipation system combined with air supply by an unmanned aerial vehicle, which comprises the following.

A box cover 1, wherein a middle section of the box cover is provided with a groove for increasing a surface area, and two sides of the box cover are provided with a first air inlet.

A radar box body 2, wherein left and right sides of the radar box body are provided with an air introduction pipeline, and the first air inlet corresponds to the air introduction pipeline, so as to introduce an air flow generated by an unmanned aerial vehicle into the radar box body.

A data acquisition module heat dissipation structure 3 is arranged on the right side of the radar box body 2, wherein the data acquisition module heat dissipation structure 3 comprises a first heat dissipation portion cover plate 301, a first heat dissipation portion shell cover 302, a wind board rotating shaft 303, a wind board 304 and a counterweight 305. A second air inlet is arranged at a front end of the first heat dissipation portion shell cover 302, a second heat dissipation fan is arranged in the second air inlet, a side surface on the right side of the radar box body is provided with a through hole communicated with the first heat dissipation portion shell cover, an air duct for introducing the air flow from the first air inlet on the right side of the box cover to the air introduction pipeline on the right side of the radar box body is the first air duct, an air duct for introducing the air flow from the second air inlet to the air introduction pipeline on the right side of the radar box body is the second air duct, the wind board rotating shaft 303, the wind board 304 and the counterweight 305 jointly form an air duct switching structure, the wind board 304 is bent by 35° to make up a pressure loss of the air flow in the air duct, a high-speed data acquisition module 306 is fixed on a right side inside the box body and directly oriented to a second heat dissipation fan 307 of a first heat dissipation portion, and heat conduction glue is applied between the high-speed data acquisition module and the box body.

A laser device heat dissipation structure comprises an air guide duct, a laser device heat sink 402, a first heat dissipation fan 7, a TEC refrigeration system integrated in a laser device 401 and a control module. An air inlet of the laser device heat sink 402 is communicated with the air introduction pipeline on the left side of the radar box body 2, an air outlet of the laser device heat sink 402 is opposite to the air outlet of the radar box body 2, an air duct for introducing the air flow from the air inlet on the left side of the box cover 1 to the laser device heat sink 402 is the air guide duct, the air guide duct has an L-shaped structure, and a plurality of columnar structures are arranged in the laser device heat sink 402 to increase a contact area between the heat sink and the air. In order to keep an internal temperature of the laser device 401 stable, the laser device transfers heat generated by the laser device to the laser device heat sink 402 connected with a lower bottom surface by TEC refrigeration, and finally exports the heat from the laser radar through an external air flow. A control module 5 is fixed on a bottom surface of the box cover, and applied with the heat conduction glue to improve the heat dissipation capacity.

An optical receiving module comprises a reflecting mirror 601, an optical receiving lens set 602, a scanning mirror 603 and a scanning motor 604, wherein the scanning motor 604 is fixed on the right side inside the box body and directly oriented to the air outlet of the box body.

Various modules of the laser radar are mounted in corresponding positions before use, and the heat conduction glue is applied between the high-speed data acquisition module 306 and the box body 2, between the laser device 401 and the laser device heat sink 402, and between the control module 5 and the box cover 1.

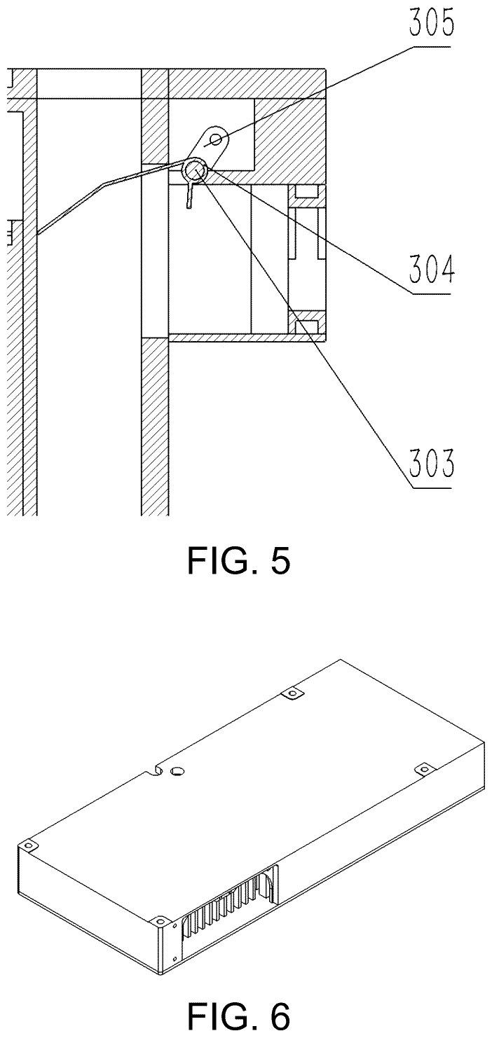

When the system starts to supply power, the high-speed data acquisition module 306 inside the laser radar starts to operate and generates heat, and the heat is transferred to the radar box body 2 through the heat conduction glue, but wings of the unmanned aerial vehicle do not rotate, so as to be unable to provide sufficient wind power, thus being easy to cause heat accumulation. At this time, the second heat dissipation fan 307 is turned on together with the high-speed data acquisition module 306, and after the second air duct generates a sufficient wind pressure, the wind board 304 is pushed open by a certain angle. When the counterweight 305 at the wind board rotating shaft 303 rotates across a balance position, a gradually increased torque is exerted on the wind board rotating shaft 303 to complete subsequent opening of the wind board 304 until the counterweight reaches a position as shown in FIG. 5. At this time, the second heat dissipation fan 307 is used to supply air to the high-speed data acquisition module through the second air duct, so as to meet heat dissipation requirements of the high-speed data acquisition module at this time.

When land configuration and other works are completed, an aerial detection task of the unmanned aerial vehicle-mounted laser radar is started. In a near-ground take-off stage of the unmanned aerial vehicle, the wings of the unmanned aerial vehicle start to rotate and generate a downward air flow, and at this time, the second heat dissipation fan 307 is still in a working state. The wind board 304 is provided with an auxiliary board structure, the air flow generated by the second heat dissipation fan 307 exerts the torque on the rotating shaft through the auxiliary board, and locks the wind board 304 together with the counterweight 305, so as to prevent dust raised from the ground from entering the radar in large amounts in the take-off stage. When it is detected that the unmanned aerial vehicle reaches a sufficient height, the control module 5 turns off the second heat dissipation fan 307 at the air inlet of the second air duct. At this time, the air flow generated by the wings of the unmanned aerial vehicle flows in from the air inlet of the first air duct, and when the sufficient wind pressure is reached, the wind board 304 is pushed. Similarly, when the wind board rotating shaft 303 rotates by a certain angle, the counterweight 305 mounted on the wind board rotating shaft rotates across the balance position to complete subsequent closing of the wind board 304. At this time, the air flow generated by the wings of the unmanned aerial vehicle passes through the first air duct to complete the heat dissipation task for the high-speed data acquisition module 306.

Specifically, when the wings of the unmanned aerial vehicle do not rotate, the second heat dissipation fan 307 is turned on, the air flow is generated in the second air duct to push open the wind board 304, the air flow acts on the wind board 304, and the torque exerted on the wind board rotating shaft 303 meets the following formula:

M₁=0.5ρAv²cₜl₁ cos θ₁

wherein, ρ represents a gas density, A represents a cross-section area of a channel, v represents a wind speed, cₜ represents a thrust coefficient of a blade, l₁ represents an equivalent arm of an air flow thrust, and θ₁ represents an included angle between the wind board and a vertical direction.

In addition to the wind board 304 of the main wind stopping structure, the wind board rotating shaft 303 is further provided with the smaller auxiliary board for locking the wind board 304 together with the counterweight 305 when the second heat dissipation fan 307 is turned on, and the torque exerted on the wind board rotating shaft 303 under an action of wind power meets the following formula:

M₂=0.5ρAv²cₜl₂ cos θ₂

The counterweight 305 is arranged on two sides of the wind board rotating shaft 303, and set at 10° away from the balance position of the counterweight in an initial state. At this time, the counterweight 305 may provide the torque as shown in the following formula:

M₃=mgl sin θ₃

In order to open the wind board 304 smoothly, the torque exerted on the wind board rotating shaft 303 should meet the following relationship formula:

$$\{ \begin{matrix}{M}_{1} + {M}_{2} - {M}_{3} > G {l}_{3} sin {θ}_{1} , {θ}_{1} < θ \\ {M}_{1} + {M}_{2} + {M}_{3} > G {l}_{3} sin {θ}_{1} , {θ}_{1} \geq θ\end{matrix}$$

wherein, G is a weight of the wind board 304, l₃ represents a distance from a center of gravity of the wind board 304 to the wind board rotating shaft 303, and θ represents an initial included angle between the counterweight 305 and the balance position.

When the counterweight 305 reaches a limit position on a right side of the balance position, the wind board 304 is completely opened, and at this time, the counterweight 305 and the auxiliary board may also prevent an air flow in a vertical direction from closing the wind board 304, so as to affect an air volume of the second heat dissipation fan 307. After the wings of the unmanned aerial vehicle rotate and the second heat dissipation fan 307 stops working, a downward air flow generated by the unmanned aerial vehicle closes the wind board 304 again, and the vertical first air duct is connected to the heat dissipation system again. At this time, the torque M₄ of the air flow generated by the unmanned aerial vehicle on the wind board rotating shaft 303 should meet the following relationship formula:

$${M}_{4} + G {l}_{I} sin {θ}_{1} > {M}_{3}$$

In the detection operation, in order to keep the temperature of the laser device stable, a second heat dissipation portion is arranged on the left side of the box body 2, wherein the laser device heat sink 402 is arranged to enhance the heat dissipation of the laser device 401, the air guide duct of the second heat dissipation portion guides the air flow generated by the wings of the unmanned aerial vehicle into the laser device heat sink 402, and the first heat dissipation fan 7 is arranged at the air outlet to exhaust air. The control module 5 adjusts power of the first heat dissipation fan 7 according to temperature requirements of the laser device, so as to meet dynamic temperature requirements of the laser device 401.

Although the implementations of the present invention have been disclosed above, the implementations are not limited to the applications listed in the specification and the embodiments, and can be fully applied to various fields suitable for the present invention, and additional modifications can be easily implemented by those skilled in the art. Therefore, the present invention is not limited to the specific details and the graphic examples shown and described herein without departing from the general concept defined by the claims and the equivalent scope.

What is claimed is:

1. A double-air-duct laser radar heat dissipation structure, comprising a radar box body, a box cover, a laser device heat dissipation structure and a data acquisition module heat dissipation structure, wherein left and right sides of the radar box body are provided with an air introduction pipeline, which introduces an air flow generated by an unmanned aerial vehicle into the radar box body; a front side of the radar box body is provided with an air outlet and a first heat dissipation fan; and left and right sides of the box cover are provided with a first air inlet corresponding to the air introduction pipeline, and a groove is arranged in a central area to increase a contact area with air for assisting heat dissipation.

2. The double-air-duct laser radar heat dissipation structure according to claim 1, wherein the data acquisition module heat dissipation structure is arranged on the right side of the radar box body, and comprises a first heat dissipation portion consisting of a first heat dissipation portion cover plate, a first heat dissipation portion shell cover, a wind board, a wind board rotating shaft, a counterweight, and a second air inlet arranged at a front end of the first heat dissipation portion shell cover and a second heat dissipation fan arranged in the second air inlet, a side surface on the right side of the radar box body is provided with a through hole communicated with the first heat dissipation portion shell cover, an air duct for introducing the air flow from the first air inlet on the right side of the box cover to the air introduction pipeline on the right side of the radar box body is the first air duct, and an air duct for introducing the air flow from the second air inlet to the air introduction pipeline on the right side of the radar box body is the second air duct; the wind board serves as a structure for switching between the first air duct and the second air duct, an auxiliary board is also arranged on the wind board rotating shaft for locking the wind board together with the counterweight when the second heat dissipation fan is turned on, and the air duct connected to the radar box body is determined by a position of the wind board; and the counterweight is arranged on two sides of the wind board rotating shaft, and set at 10° away from a balance position of the counterweight in an initial state, which prevents the wind board from being opened due to unintended activation by a weak external air flow when the second heat dissipation fan is not turned on, and is also able to serve as main power in the latter half to open the wind board when the second heat dissipation fan is turned on.

3. The double-air-duct laser radar heat dissipation structure according to claim 1, wherein the laser device heat dissipation structure comprises a second heat dissipation portion consisting of an air guide duct, a laser device heat sink, the first heat dissipation fan, a TEC refrigeration system integrated in the laser device and a control module, an air inlet of the laser device heat sink is communicated with the air introduction pipeline on the left side of the radar box body, an air outlet of the laser device heat sink is opposite to the air outlet of the radar box body, an air duct for introducing the air flow from the air inlet on the left side of the box cover to the laser device heat sink is the air guide duct, the air guide duct has an L-shaped structure, a plurality of columnar structures are arranged in the laser device heat sink to increase a contact area between the heat sink and the air, the laser device is arranged in the radar box body, the laser device heat sink is connected to a bottom surface of the laser device, the laser device transfers heat to the laser device heat sink through the TEC refrigeration system, the first heat dissipation fan is arranged in the air outlet, and the control module controls turning on and off and a rotating speed of the first heat dissipation fan.

4. The double-air-duct laser radar heat dissipation structure according to claim 2, wherein an air duct switching flow of the data acquisition module heat dissipation structure is as follows: when wings of the unmanned aerial vehicle do not rotate, the second heat dissipation fan is turned on, the air flow is generated in the second air duct, and the air flow acts on the wind board to generate a torque effect on the wind board rotating shaft, so that the wind board starts to be opened, when the counterweight rotates across the balance position, the air flow in the second air duct completes a subsequent switching step together with the counterweight, when the counterweight reaches a limit position on a right side of the balance position, the wind board is completely opened, and at this time, the counterweight and the auxiliary board also prevent an air flow in a vertical direction from closing the wind board, so as to affect an air volume in heat dissipation; and
after the wings of the unmanned aerial vehicle rotate and the second heat dissipation fan stops working, a downward air flow generated by the unmanned aerial vehicle closes the wind board again, and the first air duct is connected to the data acquisition module heat dissipation structure again, so as to introduce the air flow generated by the unmanned aerial vehicle into the data acquisition module heat dissipation structure to enhance a heat dissipation effect.
